(19) United States
(12) Patent Application Publication
(10) Pub. No.: US 2023/0145077 A1
(43) Pub. Date: May 11, 2023

(54) METHOD OF MANUFACTURING EPITAXY OXIDE THIN FILM, AND EPITAXY OXIDE THIN FILM OF ENHANCED CRYSTALLINE QUALITY MANUFACTURED THEREBY

(71) Applicant: KOREA INSTITUTE OF SCIENCE AND TECHNOLOGY, Seoul (KR)

(72) Inventors: Seung Hyub BAEK, Seoul (KR); Hyung-Jin CHOI, Seoul (KR); Sung Hoon HUR, Seoul (KR); Ji-Soo JANG, Seoul (KR); Jung Ho YOON, Seoul (KR); Seong Keun KIM, Seoul (KR); Hyun Cheol SONG, Seoul (KR); Chong Yun KANG, Seoul (KR); Ji-Won CHOI, Seoul (KR); Jin Sang KIM, Seoul (KR); Byung Chul Lee, Seoul (KR)

(73) Assignee: KOREA INSTITUTE OF SCIENCE AND TECHNOLOGY, Seoul (KR)

(21) Appl. No.: 17/961,995

(22) Filed: Oct. 7, 2022

(30) Foreign Application Priority Data
Nov. 11, 2021 (KR) 10-2021-0154425

(51) Int. Cl. C30B 33/02; H01L 41/319; C30B 29/22; C30B 23/02

(52) U.S. Cl. CPC C30B 33/02; H01L 41/319; C30B 29/22; C30B 23/025; H01L 41/1871

(57) ABSTRACT

Disclosed is a method of manufacturing an epitaxy oxide thin film of enhanced crystalline quality, and an epitaxy oxide thin film manufactured thereby according to the present invention. With respect to the manufacturing method of the epitaxy oxide thin film, which epitaxially grows an orientation film with an oxide capable of being oriented to (001), (110), and (111) on a single crystal Si substrate, because time required for raising a temperature of the orientation film up to an annealing temperature at room temperature is extremely minimized, thermal stress arising from the large difference in thermal expansion coefficients between the substrate and the orientation film is controlled, so crystalline quality of the epitaxy oxide thin film can be enhanced. Moreover, various epitaxial functional oxides are integrated into the thin film of enhanced crystalline quality so that a novel electronic device can be embodied.

### CROSS-REFERENCE TO RELATED APPLICATION

This application claims priority to Korean Patent Application No. 10-2021-0154425, filed on Nov. 11, 2021, in the Korean Intellectual Property Office, the entire contents of which are hereby incorporated by reference.

### BACKGROUND OF THE INVENTION

### Field of the Invention

The present invention relates to a method of manufacturing an epitaxy oxide thin film, and an epitaxy oxide thin film of enhanced crystalline quality manufactured thereby, with respect to the method of manufacturing the epitaxy oxide thin film, which epitaxially grows an orientation film with an oxide capable of being oriented to (001), (110), and (111) on a single crystal Si substrate, the method being configured in such a manner as to extremely minimize time required for raising a temperature of the orientation film up to an annealing temperature at room temperature, and to control thermal stress arising from a large difference in thermal expansion coefficients between the substrate and the orientation film, thereby enhancing crystalline quality of the epitaxy oxide thin film.

### Description of the Related Arts

Because an oxide composed of a combination of oxygen and one or more metal ions has various kinds of functionality, it can be applied to a device, such as an electric device, an electronic device, a magnetic device, an optical device, an energy device, and so on.

In general, the oxide has the most excellent physical property when it is in a single crystal form, and in case that this oxide of high quality is applied to a device, it is possible to develop an electronic instrument having epoch-making performance and ability that did not exist before.

Since most electronics industries have been currently accomplished based on a silicon material, it has been very high to need technologies for combining a functional oxide of high quality with a silicon substrate.

Meanwhile, in most electronics industries, since the development of technologies has been carried out on the basis of the development of devices of micro and nano scales, it is preferable that a functional oxide to be used has the form of a thin film.

In particular, because the epitaxy oxide thin film has a very low defect density, and crystalline structure of high quality, a direction of which is well defined, it is more excellent than a polycrystal thin film in light of material characteristics related with specific machinery's performance. Accordingly, when a functional composite oxide single crystal is integrated into a Si substrate, it can be utilized in a multi-functional electronic device.

However, because most of the functional composite oxide prevents an oxide thin film of high quality from being epitaxially grown on the Si substrate due to the formation of silicon dioxide and/or silicide shown on the surface of an oxide/Si, it is difficult to epitaxially grow the oxide thin film directly on the Si substrate.

Accordingly, a method of introducing an oxide buffer layer onto the Si substrate which functions as a similar single crystal oxide substrate has been applied. At this time, there should be structural similarity in lattice parameters, and so on between the buffer layer and the Si substrate, the buffer layer should be grown by a deposition process which can be expanded on a large scale at a commercially low expense, and it has been required for the growth of epitaxy heterostructures of high quality to realize excellent crystalline quality of the buffer layer.

YSZ (Yttria-stabilized zirconia, hereinafter referred to as “YSZ”) is one of the most favorable materials which can be used in an epitaxy buffer layer of Si, and the largest advantages of YSZ layer are that it can be grown by a physical vapor deposition (PVD) technique, such as a sputtering process and a pulse laser deposition (PLD) process, at a low price, and that no relatively simple ultra-high vacuum is required. In particular, sputtering has already been widely used in the industrial world in light of a rapid deposition speed, and the uniformity of a wide area.

However, it is problematic in that crystalline quality of an epitaxial YSZ buffer layer on a Si substrate is relatively poor compared with that of a competitive SrTiO₃ buffer layer which can be grown by only a molecular beam epitaxy (MBE) technique which is a process performed at a high price.

With respect to crystalline quality of the epitaxy YSZ layer on the Si substrate, in the FWHM of an X-ray diffraction (XRD) curve, because the FWHM of the YSZ buffer layer (>1°) is greater than that of the SiTiO₃ buffer layer (˜0.2°) grown by an MBE process, there is necessary to develop a process of growing an epitaxy YSZ buffer layer of high quality having crystalline quality which is the equal of that of the SrTiO₃ buffer layer.

Non-Patent Document 1 reports an effect of a buffer layer on epitaxial growth of yttria-stabilized zirconia (YSZ) deposited on SiO₂/Si (001) substrate to be matched with a crystal structure of YSZ (001) shown after deposition of the YSZ buffer layer, and in addition to this, in order to form a functional oxide single crystal thin film on a silicon substrate, the various buffer layers such as YSZ, SrTiO₃, and so on have been disclosed out. However, it is problematic in that the epitaxy oxide thin film grown by a crystal structure and a combination of atoms has a very high defect density compared to that of a silicon single crystal.

Accordingly, it is very difficult to control a crystal orientation of the epitaxy oxide thin film through direct growth. For example, it is disadvantageous in that it is impossible to deposit a perovskite functional oxide with an orientation of (110) plane or (111) plane on the Si substrate of (001) plane using a direct growth method, or even if it is deposited, crystalline quality is very poor, and these disadvantages should be settled.

Thus, the present inventors made efforts in order to epitaxially grow an orientation film with an oxide capable of being oriented to (001), (110), and (111) on a single crystal Si substrate, and to enhance crystalline quality of the epitaxy oxide thin film, and as a result thereof, the prevent invention has been completed in such a manner as to extremely minimize time required for raising a temperature of the orientation film epitaxially grown on the single crystal Si substrate up to an annealing temperature at room temperature, thereby maximizing thermal stress arising from the large difference in thermal expansion coefficients between the substrate and the orientation film, and to minimize a defect by effectively removing a dislocation of the epitaxy oxide thin film during an annealing step performed at 1,000° C. to 1,100° C., thereby ultimately confirming significantly enhanced crystalline quality of the epitaxy oxide thin film.

### PRIOR ART DOCUMENT

### Non-Patent Document

(Non-Patent Document) 1) Japanese Journal of Applied Physics 2004, 43, 1532˜1535.

### SUMMARY OF THE INVENTION

An object of the present invention is to provide a method of manufacturing an epitaxy oxide thin film, which is capable of designing epitaxy heterostructures by controlling thermal stress between a substrate and an orientation film.

Another object of the present invention is to provide an epitaxy oxide thin film of enhanced crystalline quality manufactured by the method of manufacturing the epitaxy oxide thin film.

In order to achieve the objects, the present invention may provide a method of manufacturing an epitaxy oxide thin film, with respect to the method of manufacturing the epitaxy oxide thin film, which epitaxially grows an orientation film on a single crystal Si substrate with an oxide capable of being oriented to (001), (110), and (111), the method comprising carrying out an annealing step at 1,000° C. to 1,100° C. by extremely raising a temperature raising rate until a temperature of the orientation film epitaxially grown reaches an annealing temperature at room temperature so that crystalline quality of the annealed orientation film can be enhanced.

It may be preferable that the annealing step is carried out at a temperature raising rate of 100° C. to 1,000° C./sec until the temperature of the orientation film reaches the annealing temperature at room temperature, and that the annealing step is maintained for 10 minutes to 180 minutes at 1,000° C. to 1,100° C.

The orientation film may be annealed by raising a temperature raising rate into the range of from 100° C. to 110° C./sec until its temperature reaches the annealing temperature at room temperature, and may be formed by a pulse laser deposition (PLD) method, a sputtering method, and so on.

The orientation film annealed through the manufacturing method of the present invention may be controlled by a lattice constant of 4.000 Å to 5.500 Å in a c-axis direction.

Furthermore, a full width at half maximum of the annealed orientation film may range from 0.3 to 0.6° so that the enhancement of crystalline quality can be realized.

The orientation film may be composed of any one, or one or more compounds selected from a group consisting of YSZ, CeO₂, SrTiO₃, SrZrO₃, MgO, Al₂O₃, Er₂O₃, Gd₂O₃, Pr₂O₃, and Y₂O₃.

Also, in the method of manufacturing the epitaxy oxide thin film according to the present invention, a functional oxide electrode thin film selected from a perovskite structure electrode thin film or a ferroelectric thin film may be integrated according to an orientation direction of the orientation film epitaxially grown.

The perovskite structure electrode thin film may be any one oxide electrode thin film selected from a group consisting of LSMO((La₁₋ₓ,Srₓ)MnO₃ (0≤x≤1)), LaNiO₃, LaMnO₃, SrMnO₃, and SrRuO₃, or a piezoelectric film composed of a piezoelectric single crystal having a perovskite type crystal structure ABO₃, and the ferroelectric thin film may be in a single form composed of any one selected from ferroelectric thin films based on HfO₂ having a orthorhombic structure, or in a mixed form composed of one or more films.

Furthermore, the ferroelectric thin film based on HfO₂ having the orthorhombic structure may be a HfO₂ thin film doped with any one doping material selected from a group consisting of Zr, Si, Y, Gd, La, and Sr in order to reveal ferroelectric properties.

Furthermore, the present invention may provide an epitaxy oxide thin film of enhanced crystalline quality, which is manufactured by the manufacturing method.

Specifically, the epitaxy oxide thin according to the present invention may be configured in such a manner that a single crystal Si substrate, an orientation film in which an oxide capable of being oriented to (001), (110), and (111) on the Si substrate is epitaxially grown, and a perovskite structure electrode thin film or a ferroelectric thin film composed of a single crystal or a single orientation crystal are integrated according to an orientation direction of the orientation film.

Furthermore, with respect to the epitaxy oxide thin film, the same material as that described in the sections concerning the manufacturing method of the epitaxy oxide thin film may be used in a functional oxide electrode thin film selected from the orientation film, and the perovskite structure electrode thin film, or the ferroelectric thin film.

With respect to the manufacturing method of the epitaxy oxide thin film, which epitaxially grows the orientation film with the oxide capable of being oriented to (001), (110), and (110) on the single crystal Si substrate, the present invention may provide the manufacturing method of the epitaxy oxide thin film, which is capable of designing epitaxy heterostructures in such a manner as to optimize an annealing step by extremely increasing the rate required for raising a temperature up to an annealing temperature at room temperature, and to control thermal stress naturally arising from the large difference in thermal expansion coefficients between the substrate and the orientation film.

Furthermore, epitaxial perovskite oxide heterostructures can be provided through the manufacturing method of the epitaxy oxide thin film of the present invention, and the structures can be utilized as an excellent platform to develop a new electronic device of utilizing various functions of the oxide for sensing and operation as well as helping basic understanding concerning various physical properties.

### BRIEF DESCRIPTION OF THE DRAWINGS

FIG. 1 represents a result derived from the clamping model in the form of a thin film/a substrate for showing a change dependent on temperature concerning the lattice parameter of an epitaxial YSZ layer formed on a Si substrate according to the present invention,

FIG. 2 illustrates biaxial compressive strain (the ratio of c/a) according to each annealing cycle based on the model shown in FIG. 1,

FIG. 3 illustrates strain energy per unit volume of the epitaxial YSZ layer according to each annealing cycle based on each model shown in FIG. 1,

FIG. 4 shows a temperature profile concerning each heating rate in a step of forming a thin film of YSZ/Si according to a manufacturing method of an epitaxy oxide thin film of the present invention,

FIG. 5 shows a result of measuring a lattice constant in a c-axis direction of the YSZ/Si thin film according to each heating rate shown in FIG. 4,

FIG. 6 illustrates the maximum strain energy per unit volume of the YSZ/Si thin film according to each heating rate shown in FIG. 4,

FIG. 7 shows a result of measuring crystalline quality concerning a tilting direction of YSZ/Si according to each heating rate shown in FIG. 4,

FIG. 8 shows a result of measuring surface properties of the YSZ/Si thin film formed according to the manufacturing method of the epitaxy oxide thin film of the present invention,

FIG. 9 shows a temperature profile concerning an annealing step in the manufacturing method of the epitaxy oxide thin film of the present invention,

FIG. 10 shows a result of measuring the lattice constant in the c-axis direction of the YSZ/Si thin film according to each annealing time shown in FIG. 9,

FIG. 11 shows a result concerning crystalline quality of the YSZ/Si thin film according to each annealing time shown in FIG. 9, and

FIG. 12 shows a result derived from X-ray diffraction analysis on an epitaxy thin film in which a CeO₂ thin film, or an oxide thin film having an orthorhombic structure is integrated according to the manufacturing method of the epitaxy oxide thin film of the present invention.

### DETAILED DESCRIPTION OF THE INVENTION

Hereinafter, the present invention will be described in detail.

According to a preferable exemplary embodiment for embodying a method of manufacturing an epitaxy oxide thin film according to the present invention, the present invention is described based on a method of enhancing the crystalline structure of an YSZ layer which is epitaxially grown on a single crystal Si substrate.

In general, thermal stress naturally arises from the large difference in thermal expansion coefficients between a Si substrate (˜3×10⁻⁶K⁻¹) and a YSZ layer (˜9×10⁻⁶K⁻¹), and mechanical stress occurring due to a thermal mismatch is added to the mostly thin YSZ layer because the YSZ layer is far thinner than the Si substrate, and thus the YSZ layer is biaxially deformed.

Thus, the present invention comprises a thermal treatment process with a temperature raising step, an annealing step, and a cooling step after deposition when carrying out film formation of the epitaxial YSZ layer on the Si substrate, and is designed for minimizing or eliminating a dislocation by biaxial deformation of the YSZ layer by utilizing mechanical stress energy occurring due to the thermal stress as well as heat energy.

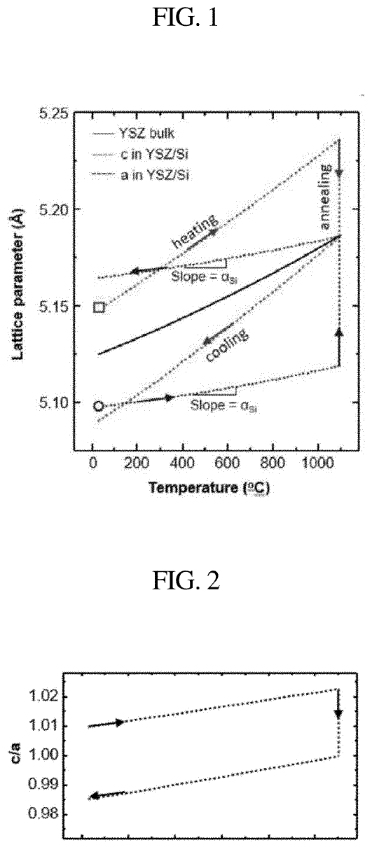

FIG. 1 show a result derived from a clamping model in the form of a thin film/a substrate for showing a change dependent on temperature concerning the lattice parameter of an epitaxial YSZ layer formed on a Si substrate according to the present invention, wherein the model in which the thin YSZ layer is fixed onto the thick Si substrate is set up, and because a difference in thicknesses between the YSZ layer (45 nm) and the Si substrate (500 [symbol] ) is large, it is assumed that a change in transformation ratio dependent on the temperature of the YSZ layer is controlled by expansion or contraction.

As a result thereof, an in-plane lattice parameter of the YSZ layer changes according to a tilt of thermal expansion coefficients of the Si substrate (blue-colored circle shown in FIG. 1), and as a result of measuring an out-of-plane lattice parameter of the YSZ layer as a temperature constant which causes a temperature to reach 1100° C. at room temperature (red-colored square shown in FIG. 1), it can be confirmed that a tilt of the lattice parameter is identical to that of a lattice parameter of the Si substrate (lower than that of a lattice parameter of YSZ bulk), and the tilt of the out-of-plane lattice parameter of the YSZ layer tends to be steeper than that of the YSZ bulk. Based on the facts as above, it can be confirmed that the out-of-plane lattice parameter of the YSZ layer is decided by biaxial deformation. Furthermore, based on the path indicated by a dotted line, it can be confirmed that there is no strain relaxation extremely during a heating step and a cooling step, and strain relaxation occurs perfectly in an annealing step at 1100° C.

FIG. 2 illustrates biaxial compressive strain (the ratio of c/a) according to each annealing cycle with respect to the models shown in FIG. 1, and shows a tetragonal distortion of the cubic YSZ layer.

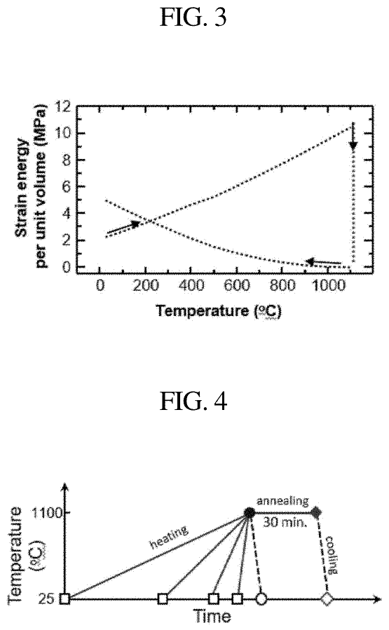

FIG. 3 illustrates strain energy per unit volume of the epitaxial YSZ layer according to each annealing cycle based on the model shown in FIG. 1, wherein the maximum mechanical strain energy per unit volume resulting from YSZ/Si is calculated at about 10 MPa, and it can be effectively used in getting rid of dislocation density by functioning as mechanical energy in addition to heat energy.

Based on the result as above, it is determined that an amount of strain relaxation during heating is relevant to time required for heating the specimen at an annealing temperature (1100° C.) under room temperature, and at this time, a heating rate functions as an important variable to control the strain energy at the annealing temperature.

In the present invention, in order to effectively utilize the thermal stress, it is important to maintain a state of the maximum strain without a loss until the temperature reaching the annealing step after film forming. Thus, when the specimen is rapidly heated (a temperature raising rate of ˜110° C./s), mechanical strain energy is maintained until the temperature of the specimen reaches the annealing temperature, whereas when the specimen is slowing heated (a temperature raising rate of ˜0.1° C./s), as a result of strain relaxation occurring in a process of the temperature raising step, it can be confirmed that a large amount of mechanical energy is released.

Furthermore, as it is confirmed that the mechanical strain energy obtained through the annealing step after film forming is important for the enhancement of crystalline quality of the YSZ layer on the Si substrate, the annealing step can be optimized.

Thus, the present invention is based on the method of enhancing crystalline quality of the YSZ layer which is epitaxially grown on the Si substrate, and with respect to the method of manufacturing the epitaxy oxide thin film, which epitaxially grows an orientation film with an oxide capable of being oriented to (001), (110), and (111) on the single crystal Si substrate, the present invention provides the method of manufacturing the epitaxy oxide thine film resulting from enhancing crystallinity of an annealed orientation film by extremely minimizing the time required for raising temperature of the orientation film epitaxially grown up to an annealing temperature at room temperature, and performing the annealing step at 1,000° C. to 1,100° C.

In the step as above, concerning a temperature raising rate until the temperature reaches the annealing temperature at room temperature, because a crack or buckling phenomenon occurs from the thin film when the temperature of the thin film increases or decreases rapidly, the temperature raising rate may be decided at the best rapid rate so that annealing can be performed within a scope in which this phenomenon doesn't occur.

A process, such as rapid thermal annealing (RTA), flash light annealing (FLA), laser annealing, and so on, in which thermal treatment can be performed at a rapid temperature raising rate, is available, and a method of improving the temperature raising rate by rapidly moving the specimen so as to reach a high temperature part in the center of a tube furnace from a room temperature part outside the tube in conventional tube furnaces is also available.

According to the exemplary embodiment of the present invention, although it is described that the temperature raising rate ranges from 100° C./sec to 110° C./sec, because the temperature raising rate may become different according to a material, the temperature raising rate may range from 100° C./sec to 1,000° C./sec as the maximum value.

FIG. 4 shows a temperature profile concerning each heating rate shown in a step of forming YSZ/Si thin film according to the manufacturing method of the epitaxy oxide thin film of the present invention, and, specifically, the time required for reaching the annealing temperature of 1100° C. at room temperature is changed to 10 seconds, 10 minutes, 30 minutes, and 240 minutes, and each heating rate is set up as ˜110° C./s, ˜1.8° C./s, ˜0.6° C./s, and ˜0.1° C./s.

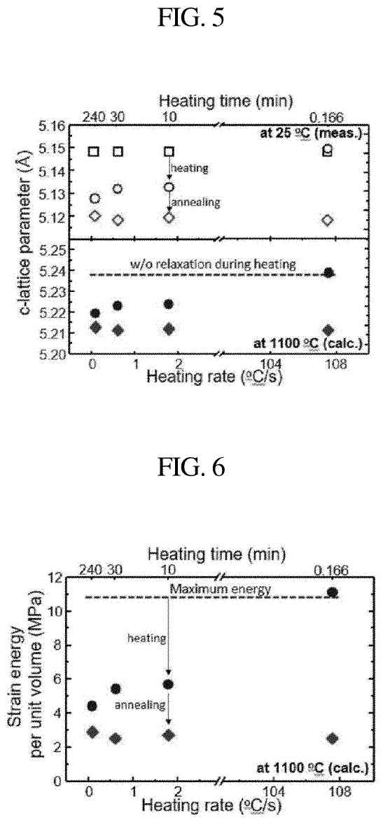

FIG. 5 shows a result of measuring a lattice constant in the c-axis direction according to each heating rate, and as the experimental result derived at 25° C. as described in the top, a degree of strain relaxation shows an almost fixed result without any connection with each heating rate. The lattice constant in the c-axis direction of the annealed orientation film is controlled in the range of 4.000 Å to 5.500 Å.

Based on the result, it can be confirmed that when a distance between the temperature raising step and the annealing step is calculated, strain relaxation occurs from the specimen slowly heated at the temperature raising rate of ˜0.1° C./s mainly during heating, whereas strain relaxation occurring from the specimen rapidly heated at the temperature raising rate of ˜110° C./s doesn't almost occur during heating, but mostly occurs in the annealing step.

On the assumption that there is no relaxation during the heating process as shown in the bottom of FIG. 5, it can be confirmed that the result trends to be consistent with a value calculated at 1100° C.

FIG. 6 illustrates the maximum strain energy per unit volume of YSZ/Si according to each heating rate, and when the temperature of the YSZ layer just reaches 1100° C. at room temperature, and when 30 minutes' annealing is just finished at 1100° C., with respect to the strain energy per unit volume of the YSZ layer, the sample slowly heated is provided with more much heat energy than that of the sample rapidly heated.

On the other hand, in an initial step of annealing performed at 1100° C., because residual strain energy of the rapidly heated specimen is greater than that of the slowly heated specimen, the residual strain energy is mostly released at 1100° C. (high temperature). On the contrary, in case of the slowing heated specimen, the residual strain energy is mostly released at a low temperature.

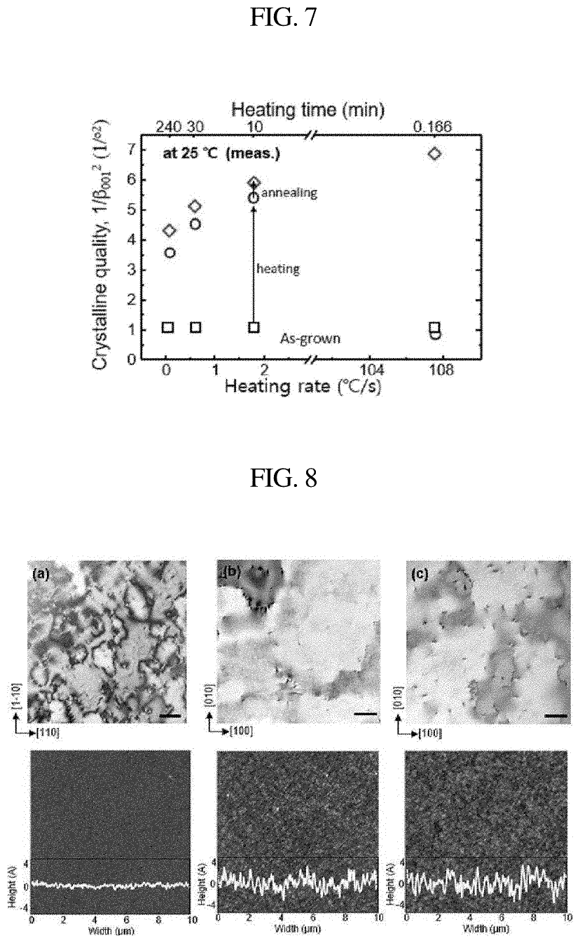

FIG. 7 shows a result of measuring crystalline quality concerning a tilting direction of the YSZ/Si thin film according to each heating rate, and it can be confirmed that the crystalline quality of the YSZ layer is enhanced as the heating rate increases.

Furthermore, even though the total heat energy applied to the rapidly heated specimen is far smaller than that of the slowly heated specimen, its crystalline quality shows a far significantly enhanced result.

From the above, in an embodiment of the method for manufacturing an epitaxial oxide thin film of the present invention, it is performed at a temperature raising rate of 100° C./sec to 110° C./sec until a temperature of the orientation film reaches the annealing temperature at room temperature, and the annealing step is maintained at 1,000 to 1,100° C. for 10 to 180 minutes. It is optimized to perform under conditions.

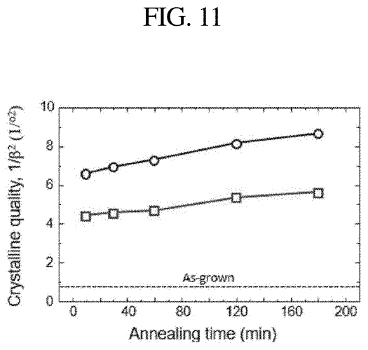

As a result of carrying out an experiment in order to confirm an effect on crystalline quality of the epitaxy oxide thin film according to each annealing time, as confirmed through FIG. 10 and FIG. 11, in case that annealing is carried out after the specimen is heated at a rapid heating rate, although there is no large difference in lattice constants in the c-axis direction according to an increase in annealing time, it can be confirmed that the crystalline quality of the YSZ layer is enhanced in proportion to an increase in annealing time.

Although one exemplary embodiment concerning the method of manufacturing the epitaxy oxide thin film of the present invention is described in a state of laying emphasis on YSZ, the exemplary embodiment will not be limited thereto if a process characteristic according to the manufacturing method of the epitaxy oxide thin film of the present invention is applied to other exemplary embodiments, and any one, or one or more compounds selected from a group consisting of YSZ, CeO₂, SrTiO₃, SrZrO₃, MgO, Al₂O₃, Er₂O₃, Gd₂O₃, Pr₂O₃, and Y₂O₃ can be applied. The orientation film annealed by the manufacturing method of the present invention is controlled by a lattice constant of 4.000 to 5.500 Å in the c-axis direction, and the full width at half maximum (FWHM) of the annealed orientation film is 0.3° to 0.6°, so the enhancement of crystalline quality is realized.

In the method of manufacturing the epitaxy oxide thin film of the present invention, a functional oxide electrode thin film selected from a perovskite structure electrode thin film or a ferroelectric thin film may be integrated according to an orientation direction of the orientation film epitaxially grown.

According to one example of the functional oxide electrode thin film, any one oxide electrode thin film selected from a group consisting of LSMO((La₁₋ₓ,Srₓ)MnO₃ (0≤x≤1)), LaNiO₃, LaMnO₃, SrMnO₃, and SrRuO₃ can be used as the perovskite structure electrode thin film.

Furthermore, according to another example of the functional oxide electrode thin film, a piezoelectric film composed of a piezoelectric single crystal with a perovskite type crystal structure (ABO₃) having a compositional formula of Formula 1 below can be used.

[A_{1-(a+1.5b)}BₐC_{b}][(MN)_{1-x-y}(L)_{y}Tiₓ]O₃ Chemical Formula 1

In the formula, A represents Pb or Ba,

B represents at least one or more elements selected from a group consisting of Ba, Ca, Co, Fe, Ni, Sn, and Sr,

C represents one or more elements selected from a group consisting of Co, Fe, Bi, La, Ce, Pr, Nd, Pm, Sm, Eu, Gd, Tb, Dy, Ho, Er, Tm, Yb, and Lu,

L represents a single form composed of one element selected from Zr or Hf, or a mixed form thereof,

M represents at least one or more elements selected from a group consisting of Ce, Co, Fe, In, Mg, Mn, Ni, Sc, Yb, and Zn,

N represents at least one or more elements selected from a group consisting of Nb, Sb, Ta, and W, and

a, b, x, and y satisfy the following requisites: 0<a≤0.10, 0<b≤0.05, 0.05≤x≤0.58, and 0.05≤y≤0.62.

Preferably, in the formula, a piezoelectric single crystal which satisfies the requisites of 0.01≤a≤0.10 and 0.01≤b≤0.05 is used, and, more preferably, satisfying a requisite of a/b≥2. At this time, in the requisites, when a is less than 0.01, it is problematic in that a perovskite phase is unstable, and when a exceeds 0.10, it is not preferable in that it is difficult to use the piezoelectric single crystal really because a phase transition temperature becomes too low.

Also, if the requisite of a/b≥2 is not satisfied, it will not be preferable because it is problematic in that dielectric and piezoelectric characteristics are not maximized, or growth of the single crystal is limited.

With respect to the piezoelectric single crystal of the perovskite type crystal structure ABO₃ having the compositional formula of the chemical formula 1, based on a tendency which shows that as chemical composition becomes complex, the more the piezoelectric characteristic increases, in the perovskite type crystal structure (ABO₃), the ions located at [A] are constituted of mixed composition of [A_{1-(a+1.5b)}BₐC_{b}]. At this time, in the piezoelectric single crystal having the compositional formula of Chemical Formula 1, with respect to the mixed composition of the ions located at [A], when the composition is the mixed composition compared with the case in which the ions are constituted of a metal³⁺ or a metal²⁺ independently, an excellent dielectric constant may be realized.

More preferably, the piezoelectric single crystal having the compositional formula of Chemical Formula 1 includes a metal⁴⁺ element as an ion located at [B] in the perovskite type crystal structure ABO₃, and in particular, composition of L is limited to a single form composed of one element selected from Zr or Hf, or a mixed form thereof. More preferably, it includes a perovskite piezoelectric oxide containing Zr grown by a solid phase growth method, and even though the perovskite piezoelectric oxide including a pore occurring in a process of the solid phase growth method is used, the piezoelectric single crystal is formed into a thin film in which no pore exists.

More specifically, in the piezoelectric single crystal, when L represents the mixed form, it has a compositional formula of Chemical Formula 2 or Chemical Formula 3.

[A_{1-(a+1.5b)}BₐC_{b}][(MN)_{1-x-y}(Zr_{1-w},Hf_{w})_{y}Tiₓ]O₃ Chemical Formula 2

[A1_{-(a+1.5b)}BₐC_{b}][(MN)_{1-x-y}(Zr_{1-w},Hf_{w})_{y}Tiₓ]O_{3-z} Chemical Formula 3

In each of the formulae, A, B, C, M, N, a, b, x, y, and z represent the same conditions as those of said Chemical Formula 1, and w satisfies the requisite of 0.01≤w≤0.20.

Thus, according to the present invention, although the composition is complicated chemical composition using a solid phase single crystal growth method, the piezoelectric single crystal of uniform composition is used irrespective of the composition, and based on the complicated composition of the ions located at [A], the oxide electrode thin film of the perovskite structure is formed of a piezoelectric single crystal with dielectric characteristics, such as a high dielectric constant K_{3T}, high piezoelectric constants d₃₃ and k₃₃, high phase transition temperatures T_{C} and T_{RT}, and a high coercive electric field Ec.

Furthermore, with respect to another one example of the functional oxide electrode thin film, a ferroelectric thin film may include an oxidized film of an orthorhombic structure, it may be preferable to use a ferroelectric thin film based on HfO₂ having the orthorhombic structure, and HfO₂ doped with any one selected from a group consisting of Zr, Si, Y, Gd, La, and Sr may be used in the ferroelectric thin film based on HfO₂ of the orthorhombic structure.

In the exemplary embodiment of the present invention, the oxide electrode thin film having the orthorhombic structure is described based on Y doped HfO₂ (YHO), but is not limited thereto.

Furthermore, the present invention provides an epitaxy oxide thin film of enhanced crystalline quality manufactured by the manufacturing method.

Specifically, the present invention provides the epitaxy oxide thin film in which a single crystal Si substrate, an orientation film on which an oxide capable of being oriented to (001), (110), and (111) on the Si substrate is epitaxially grown, and a perovskite structure electrode thin film composed of a single crystal or a single orientation crystal are integrated deposited according to an orientation direction of the orientation film.

With respect to the epitaxy oxide thin film, the same materials as those described in the sections concerning the manufacturing method of the epitaxy oxide thin film are used in the orientation film, and the functional oxide electrode thin film selected from a perovskite structure electrode thin film or a ferroelectric thin film.

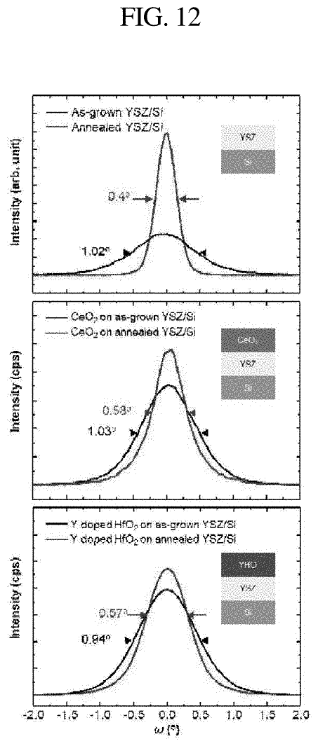

FIG. 12 shows a result derived from X-ray diffraction analysis concerning the epitaxy oxide thin film in which the oxide thin film is integrated according to the manufacturing method of the epitaxy oxide thin film of the present invention, and it can be confirmed that a change in FWHM of the YSZ layer epitaxially grown on the Si substrate can be confirmed according to whether an annealing step is carried out or not, and when the annealing is carried out, the wide FWHM)(>1° largely reduces to ˜0.4°, whereas intensity of a diffraction peak increases up to ˜4 times.

Thus, the annealed orientation film of the present invention is embodied so as to have the FWHM of 0.3 to 0.6°, and based on the result which shows that the FWHM after annealing reduces from 30% to 50%, it is supported that crystallinity is enhanced.

Even when CeO₂ deposited on the YSZ layer is put up, the FWHM is maintained in a state of being 0.58°, and it can be confirmed that because the intensity of the diffraction peak also shows a similar pattern, when the YSZ layer is epitaxially grown on the Si substrate stably, crystallinity of the oxide thin film having the perovskite structure integrated according to an orientation direction of the YSZ layer is also enhanced. Furthermore, because the CeO₂ also functions as a buffer layer, the stable thin film can be formed by epitaxially growing the functional oxide layer having the perovskite structure on the CeO₂ layer.

In case of Y doped HfO₂ (YHO) deposited on the YSZ layer manufactured in Example 2, it is confirmed that its FWHM is also 0.57°, and because the intensity of a diffraction peak also shows a similar pattern, it can be confirmed that crystallinity of the ferroelectric thin film based on HfO₂ having an orthorhombic structure is enhanced thanks to crystalline quality of YSZ epitaxially grown on the Si substrate. When the Y doped HfO₂ (YHO) grows into the orthorhombic crystal structure, it becomes to have a ferroelectric property, thereby functioning as a functional oxide in itself.

An epitaxial perovskite oxide hetero structure can be provided through the manufacturing method of the epitaxy oxide thin film of the present invention, and the structure can be utilized as an excellent platform for the improvement of a novel electronic device of utilizing various functions of the oxide for sensing and operation as well as helping basic understanding of various physical properties.

Specifically, it is possible to manufacture a sensor, an actuator, a transducer, or a microelectromechanical system (MEMS) as well as a novel electronic device or an optical device by integrating various epitaxial function oxides into the thin film of enhanced crystalline quality.

Hereinafter, the present invention is described in more detail based on Examples.

The present examples are intended for more specifically describing the present invention, and the scope of the present invention should not be limited to these examples.

### Example 1

001-oriented Si single crystal substrates with a native oxide layer on the surface were prepared. The epitaxial YSZ thin films were grown by pulsed laser deposition (PLD) with a KrF excimer laser (A=248 nm) under 0.1 mTorr O₂ partial pressure with a laser energy density of 1.5 J/cm² and a frequency of 5 Hz at 750° C. YSZ ceramic target with a composition of 10% Y—ZrO₂ were used with a sample-to-target distance of 5 cm. The growth rate is 6 nm/min.

Thermal annealing was performed in a state of a specimen of YSZ/Si in which an epitaxial YSZ thin film is deposited on the Si single crystal substrate being put into a tube furnace. At this time, a temperature shown in a place located in the center of the tube furnace was set up as 1100° C., oxygen gas was flowing at 10 sccm, a heating rate was controlled by the time it take to push the specimen on top of the quartz boat from the edge to the center positions.

The YSZ/Si specimen was subjected to thermal treatment for 10 seconds under the condition of a temperature raising rate of 110° C./sec until its temperature reaching a temperature of 1100° C. at room temperature. After the thermal treatment, the specimen was annealed for 30 minutes at 1100° C., and was cooled for 10 seconds at room temperature.

An epitaxy oxide thin film was manufactured in such a manner as to grow CeO₂ (cubic, a=5.4 Å) intended for deposition of a perovskite oxide layer on the YSZ buffer layer of the annealed YSZ/Si specimen, and to epitaxially grow the perovskite oxide layer of (La_{0.67}, Sr_{0.33})MnO₃ (LSMO) at an in-plane rotation of 45° at an upper part of the CeO₂ layer.

### Example 2

The same processes as those of said Example 1 were performed except the fact that Y doped HfO₂ (Orthorhombic, a=5.07 Å, b=5.24 Å, c=5.08 Å) was epitaxially grown on the YSZ buffer layer of the annealed YSZ/Si specimen, thereby manufacturing the epitaxy oxide thin film.

### Example 3

The same processes as those of said Example 1 were performed except the fact that the YSZ/Si specimen was thermally treated for 10 minutes under the condition of a temperature raising rate of 1.8° C./sec until its temperature reaching 1100° C. at room temperature, was annealed for 30 minutes, and was then cooled for 10 seconds at room temperature.

### Example 4

The same processes as those of said Example 1 were performed except the fact that the YSZ/Si specimen was thermally treated for 30 minutes under the condition of the temperature raising rate of 0.6° C./sec until its temperature reaching 1100° C. at room temperature, was annealed for 30 minutes at 1100° C., and was cooled for 10 seconds at room temperature.

### Example 5

The same processes as those of said Example 1 were performed except the fact that the YSZ/Si specimen was thermally treated for 240 minutes under the condition of the temperature raising rate of 0.1° C./sec until its temperature reaching 1100° C. at room temperature, was annealed for 30 minutes at 1100° C., and was cooled for 10 seconds at room temperature.

### Comparative Example 1

The same processes as those of said Example 1 were performed except the fact that the YSZ/Si specimen was thermally treated for 10 seconds under the condition of the temperature raising rate of 110° C./sec until its temperature reaching 1100° C. at room temperature, and was cooled for 10 seconds at room temperature without annealing.

### Comparative Example 2

The same processes as those of said Example 1 were performed except the fact that the YSZ/Si specimen was thermally treated for 10 minutes under the condition of the temperature raising rate of 1.8° C./sec until its temperature reaching 1100° C. at room temperature, and was cooled for 10 seconds at room temperature without annealing.

### Comparative Example 3

The same processes as those of said Example 1 were performed except the fact that the YSZ/Si specimen was thermally treated for 30 minutes under the condition of the temperature raising rate of 0.6° C./sec until its temperature reaching 1100° C. at room temperature, and was cooled for 10 seconds at room temperature without annealing.

### Comparative Example 4

The same processes as those of said Example 1 were performed except the fact that the YSZ/Si specimen was thermally treated for 240 minutes under the condition of the temperature raising rate of 0.1° C./sec until its temperature reaching 1100° C. at room temperature, and was cooled for 10 seconds at room temperature without annealing.

### <Experimental Example 1> Evaluation on Physical Properties of a Thin Film According to Each Heating Rate

In each step of forming the YSZ layer epitaxially grown on the Si substrate as performed in said Examples 1 to 4 and Comparative Examples 1 to 4, evaluation on lattice constants in a c-axis direction of the thin film, and crystalline quality according to each heating rate was performed.

1. Measurement of the Lattice Constants in the c-Axis Direction

FIG. 4 shows a temperature profile concerning a heating rate in each step of forming the YSZ/Si layer according to the method of manufacturing the epitaxy oxide thin film of the present invention, wherein each of red-colored solid lines represents a temperature raising step performed by varying the heating rate until a temperature reaches 1100° C., and each of black-colored dotted lines represents a cooling step performed for 10 seconds after performing each step.

Furthermore, each of quadrilaterals whose inside is empty means an as-grown state, each of blue-colored circles whose inside is full means a state right after the temperature reached 1100° C., each of blue-colored circles whose inside is empty means a state of performing cooling for 10 seconds right after the temperature reached 1100° C., each of red-colored lozenges whose inside is full means a state of performing annealing for 30 minutes right after the temperature reaches 1100° C., and each of red-colored lozenges whose inside is empty means a state of performing cooling for 10 seconds after annealing.

FIG. 5 shows a result of measuring lattice constants in the direction c-axis of the YSZ/Si layer according to each heating rate, wherein the top shows experimental values resulting from carrying out a thermal process according to each step, and the bottom shows calculated values at 1100° C.

Based on the result shown in said FIG. 5, each of quadrilaterals, the inside of which is empty, and which shows the as-grown state according to each heating rate until the temperature reached 1100° C. showed a lattice constant value in the c-axis direction of the YSZ layer, which is uniform irrespective of the heating rates.

Furthermore, each of red-colored lozenges whose inside is empty, and which shows a state of performing cooling for 10 seconds after 30 minutes' annealing after an annealing temperature reaches 1100° C., also showed a lattice constant value in the c-axis direction, which is smaller than that in the as-grown state, and which is almost uniform. As above, it was confirmed that the YSZ layer was relaxed during being annealed, and a degree of strain relaxation didn't depend upon the heating rates, but was almost uniform.

This result shows that a strain relaxation part occurred between the temperature raising step and the annealing step after film forming, and, as seen from FIG. 5, a distance between each of the black-colored quadrilaterals whose inside is empty and each of the blue-colored circles whose inside is empty, and a distance between each of the blue-colored circles whose inside is empty and each of the red-colored lozenges whose inside is empty could be calculated. At this time, the strain relaxation part of each step changed according to each heating rate, and, specifically, it was confirmed that strain relaxation from a sample slowly heated at a rate of 0.1° C./s mainly occurred during heating, whereas strain relaxation from a sample quickly heated at a rate of ˜110° C./s didn't almost occur, but mostly occurred in the annealing step.

Based on these results, as illustrated at the bottom of FIG. 5, the lattice constants in the c-axis direction at 1100° C. (indicated by the solid lined circles and lozenges) were calculated, and based on the calculated values, as a heating rate constant, strain energy existing in the YSZ layer at 1100° C. in each annealing process during the heating process could be calculated by the following formula.

$$E = \frac{{( {a}_{f} - {a}_{0} )}^{2}}{{a}_{0}^{2} ( {S}_{11} - {S}_{12} )}$$

In the formula, a_{f} and a₀ represent an in-plane lattice parameter and a bulk lattice parameter of the YSZ layer, respectively, and S represents an elastic compliance of the YSZ layer.

FIG. 6 illustrates the maximum strain energy per unit volume of the layer of YSZ/Si according to each heating rate, wherein the black-colored dotted line presents a value resulting from calculating the maximum strain energy per unit volume of the YSZ layer at 1100° C. when heating is performed without relaxation.

As a result, each of the blue-colored circles and the red-colored lozenges shows strain energy per unit volume of the YSZ layer when the YSZ layer has just arrived at 1100° C. from room temperature and when annealing for 30 minutes at 1100° C. is just finished, and at this time, it was confirmed that when the conditions of the annealing step and the cooling step were fixed, only the heating rate was changed, more much thermal energy could be supplied to the sample slowly heated rather than the sample quickly heated.

On the contrary, in the early part of annealing performed at 1100° C., because residual strain energy of the sample quickly heated is greater than that of the sample slowing heated, the residual strain energy is mostly released at 1100° C. (high temperature). On the other hand, in case of the sample slowly heated, the residual strain energy is released at a low temperature.

2. Evaluation on Crystalline Quality

In order to evaluate crystalline quality of the YSZ layer, and in order to evaluate tilting (along the an out-of-plane direction) and twisting (along the an in-plane direction), a full width at half maximum (FWHM) concerning a rocking curve of (001) peak, β₀₀₁ and a full width at half maximum concerning a phi scan curve of (101) peak, β₁₀₁, which were observed, were measured.

Because screw dislocation density and edge dislocation density are proportionate to β₀₀₁² and β₁₀₁², respectively, crystalline quality from a tilting and twisting surface was evaluated with constants of the heating rate by plotting of 1/β₀₀₁² and 1/β₁₀₁² as shown in FIG. 7.

It is clear that the crystalline quality of YSZ layer is getting better as the heating rate increases. Even though the total thermal energy applied to the fast-heated sample is much smaller than that of the slow-heated sample, the crystalline quality becomes improved a lot higher.

This result indicates that the strain energy arising from the thermal mismatch plays an important role to effectively improve the crystalline quality of the YSZ layer on Si.

### <Experimental 2> Evaluation on Surface Properties

In order to evaluate a defect in a surface of the thin film of YSZ/Si formed according to the method of manufacturing the epitaxy oxide thin film, a surface shape and surface roughness were conformed using transmission electron microscope (TEM) and atomic force microscope (AFM) analyses.

FIG. 8 shows defects in the surface, and surface roughness of YSZ/Si thin film manufactured according to the manufacturing method of the epitaxy oxide thin film of the present invention, wherein (A) shows an as-grown state of a YSZ/Si specimen, (B) shows a YSZ/Si specimen annealed for 30 minutes at 1100° C. and rapidly cooled up to room temperature after being grown at a rapid heating rate (107.5° C./s), and (C) shows a YSZ/Si specimen annealed for 30 minutes at 1100° C. and rapidly cooled at room temperature after being grown at a slow heating rate (0.1° C./s).

The top of FIG. 8 shows TEM images of planes each having a scale bar of 50 nm, and the bottom shows surface roughness forms measured by AFM.

As a result thereof, in case of the YSZ/Si specimen shown in (A), a smooth surface having an RMS roughness of ˜0.1 nm appeared, and although TEM couldn't almost be estimated, threading dislocations each having very high density appeared, and the FWHM was about ˜1°.

Furthermore, in case of (C) which shows the YSZ/Si specimen annealed for 30 minutes at 1100° C. after being grown at a slow heating rate (0.1° C./s), it was confirmed that each density of the threading dislocations reduced to ˜460 μm⁻², and the surface had an RMS roughness of ˜0.35 nm and still showed the flat surface.

On the contrary, in case of (B) which shows the YSZ/Si specimen annealed for 30 minutes at 1100° C. after being grown at the rapid heating rate (107.5° C./s), each density of the threading dislocations more reduced to ˜220 μm⁻², and the surface was a flat surface having an RMS roughness of ˜0.4 nm. From this, it was confirmed that when the specimen was cooled at the rapid heating rate, no crack occurred on the surface of the YSZ layer.

### <Experimental Example 3> Evaluation on Physical Properties of the Thin Film According to Each Annealing Time

In the step of forming the YSZ layer epitaxially grown on the Si substrate, heating was performed at heating rates of different conditions, namely, a slow heating rate (˜0.1° C./s, red-colored) and a rapid heating rate (˜110° C./s, blue-colored) until a temperature reached 1100° C., and annealing was then performed at the temperature for an annealing time not exceeding 10 minutes to 180 minutes.

Hereinafter, an effect on crystalline quality of the thin film based on lattice constants in a c-axis direction of YSZ/Si according to each annealing time was measured.

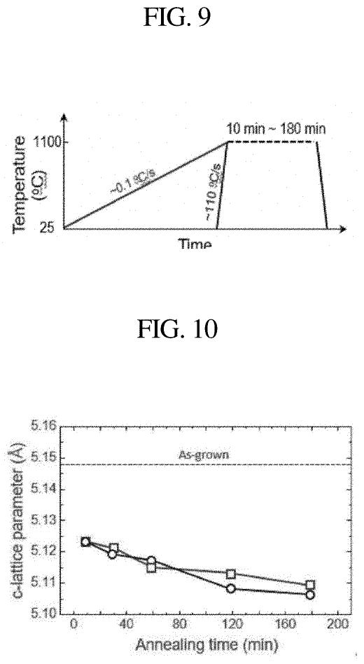

FIG. 9 shows a temperature profile concerning an annealing step in the manufacturing method of the epitaxy oxide thin film of the present invention, and FIG. 10 shows measurement values of lattice constants in the c-axis direction of YSZ/Si according to each annealing time measured at 25° C. under the condition of such a temperature profile, wherein the lattice constants were not almost influenced by a rapid heating rate or slow heating rate, and although the lattice constants in the c-axis direction reduced to some degree according to an increase in annealing time, there was no large difference.

FIG. 11 shows a result concerning crystalline quality of YSZ/Si according to each annealing time, and according to each heating rate, in particular, in case of being manufactured at a rapid heating rate, the crystalline quality of the YSZ layer was significantly enhanced. Furthermore, as the annealing time increased, crystalline quality was also enhanced in proportion to such an increase.

Comparing Case (1) in which a specimen was annealed for 180 minutes at a slow heating rate (˜0.1° C./s, red-colored) with Case (2) in which a specimen was annealed for 10 minutes at a rapid heating rate (˜110° C./s, blue-colored), although the former showed that the total annealing time (˜10 minutes) including the heating step was far smaller than that (˜7 hours) shown in the latter, crystalline quality shown in the latter was excellent.

Accordingly, with respect to the YSZ layer epitaxially grown on the Si substrate, it could be confirmed that the condition of the rapid heating rate had a considerable effect on improving the crystalline quality of the thin film, and as this result, it could be also confirmed that a dislocation was effectively removed by additional mechanical strain energy.

### <Experimental Example 4> X-Ray Diffraction Analysis on the Deposited Epitaxy Oxide Thin Film

In said Example 1, with respect to the epitaxy oxide thin film in which CeO₂ was deposited on the YSZ/Si layer, and in said Example 2, with respect to the epitaxy oxide thin film in which the Y doped HfO₂ thin film was deposited on the YSZ/Si layer, an effect resulting from carrying out the annealing step was evaluated through the X-ray diffraction analysis.

According to the result shown in FIG. 12, based on an X-ray diffraction (XRD) rocking curve at the peak of (001) of the YSZ layer before and after annealing, it was confirmed that the YSZ layer grown on the Si substrate (annealing not being carried out) showed as having the wide FWHM)(>1°.

On the contrary, as a result, it was confirmed that after annealing was performed for 4 hours at 1100° C. and at the rapid heating rate of 110° C./s, the FWHM largely reduced to ˜0.4°, whereas intensity of the diffraction peak increased up to 4 times after annealing.

Furthermore, even when CeO₂ deposited on the YSZ layer of the thin film was put, the FWHM was maintained as 0.58°, and as it was confirmed that the intensity of the diffraction peak showed a similar pattern, it was confirmed that when the YSZ layer was stably epitaxially grown on the Si substrate, the oxide thin film having the perovskite structure was smoothly integrated according to the orientation direction of the YSZ layer.

In case of the Y doped HfO₂ (YHO) thin film deposited on the YSZ layer, it was also confirmed that the FWHM was 0.57°, and as the intensity of the diffraction peak also showed a similar pattern, crystallinity of the ferroelectric thin film based on HfO₂ having an orthorhombic structure was enhanced thanks to crystalline quality of the YSZ layer epitaxially grown on the Si substrate.

As previously described, although in the detailed description of the present invention, having been described only the detailed exemplary embodiments of the present invention, it should be apparent to those skilled in the art that various variations and modifications can be made within the technical scope of the present invention, and it will be apparent that these variations and modifications fall within the scope of the appended claims.

What is claimed is:

1. A method for manufacturing an epitaxial oxide thin film in which epitaxially grows an orientation film with an oxide capable of being oriented to (001), (110), (111) on a single crystal Si substrate, the method comprising of:
an annealing step of raising a temperature raising rate into the range of 100° C./sec to 1,000° C./sec until a temperature of the orientation film epitaxially grown reaches an annealing temperature at room temperature, thereby enhancing crystalline quality of the annealed orientation film.

2. The method of claim 1, wherein the annealing step is carried out at 1,000° C. to 1,100° C.

3. The method of claim 1, wherein the annealing step is maintained for 10 minutes to 600 minutes.

4. The method of claim 1, wherein the orientation film annealed is controlled by a lattice constant of 4.000 Å to 5.500 Å in a c-axis direction.

5. The method of claim 1, wherein a full width at half maximum of the annealed orientation film is 0.2° to 0.6° so that enhancement of crystalline quality is realized.

6. The method of claim 1, wherein the orientation film is composed of any one, or one or more compounds selected from a group consisting of YSZ, CeO₂, SrTiO₃, SrZrO₃, MgO, Al₂O₃, Er₂O₃, Gd₂O₃, Pr₂O₃, and Y₂O₃.

7. The method of claim 1, wherein a functional oxide electrode thin film selected from a perovskite structure electrode thin film or a ferroelectric thin film is integrated according to an orientation direction of the orientation film epitaxially grown.

8. The method of claim 7, wherein the functional oxide electrode thin film is composed of any one oxide selected from a group consisting of LSMO((La₁₋ₓ,Srₓ)MnO₃ (0≤x≤1)), LaNiO₃, LaMnO₃, SrMnO₃, and SrRuO₃.

9. The method of claim 7, wherein the functional oxide electrode thin film is composed of a piezoelectric single crystal of a perovskite type crystal structure (ABO₃) having a compositional formula of Chemical Formula 1 below:
[A_{1-(a+1.5b)}BₐC_{b}][(MN)_{1-x-y}(L)_{y}Tiₓ]O₃ Chemical Formula 1
in the formula, A represents Pb or Ba,
B represents at least one or more elements selected from a group consisting of Ba, Ca, Co, Fe, Ni, Sn, and Sr,
C represents one or more elements selected from a group consisting of Co, Fe, Bi, La, Ce, Pr, Nd, Pm, Sm, Eu, Gd, Tb, Dy, Ho, Er, Tm, Yb, and Lu,
L represents a single form composed of one element selected from Zr or Hf, or a mixed form thereof,
M represents at least one or more elements selected from a group consisting of Ce, Co, Fe, In, Mg, Mn, Ni, Sc, Yb, and Zn,
N represents at least one or more elements selected from a group consisting of Nb, Sb, Ta, and W, and
a, b, x, and y satisfy requisites: 0<a≤0.10, 0<b≤0.05, 0.05≤x≤0.58, and 0.05≤y≤0.62.

10. The method of claim 9, wherein, in the formula, a piezoelectric single crystal satisfies the requisites of 0.01<a≤0.10 and 0.01<b≤0.05.

11. The method of claim 7, wherein the functional oxide electrode thin film is composed of a ferroelectric thin film based on HfO₂ having an orthorhombic structure.

12. The method of claim 11, wherein the ferroelectric thin film based on HfO₂ having the orthorhombic structure is a thin film of HfO₂ doped with any one selected from a group consisting of Zr, Si, Y, Gd, La, and Sr.

13. An epitaxy oxide thin film of enhanced crystalline quality, which is manufactured by the manufacturing method of any one claim among claim 1,
comprising of a single crystal Si substrate,
an orientation film in which an oxide capable of being oriented to (001), (110), and (111) on the Si substrate is epitaxially grown, and
a functional oxide electrode thin film selected from a perovskite structure electrode thin film or a ferroelectric thin film composed of a single crystal or a single orientation crystal are integrated according to an orientation direction of the orientation film.

14. The epitaxy oxide thin film of claim 13, wherein the orientation film is composed of any one, or one or more compounds selected from a group consisting of YSZ, CeO₂, SrTiO₃, SrZrO₃, MgO, Al₂O₃, Er₂O₃, Gd₂O₃, Pr₂O₃, and Y₂O₃.

15. The epitaxy oxide thin film of claim 13, wherein the functional oxide electrode thin film is composed of any one oxide selected from a group consisting of LSMO((La₁₋ₓ,Srₓ)MnO₃ (0≤x≤1)), LaNiO₃, LaMnO₃, SrMnO₃, and SrRuO₃.

16. The epitaxy oxide thin film of claim 13, wherein the functional oxide electrode thin film is a piezoelectric film composed of a piezoelectric single crystal of a perovskite type crystal structure (ABO₃) having a compositional formula of Chemical Formula 1 below:
[A_{1-(a+1.5b)}BₐC_{b}][(MN)_{1-x-y}(L)_{y}Tiₓ]O₃ Chemical Formula 1
in the formula, A represents Pb or Ba,
B represents at least one or more elements selected from a group consisting of Ba, Ca, Co, Fe, Ni, Sn, and Sr,
C represents one or more elements selected from a group consisting of Co, Fe, Bi, La, Ce, Pr, Nd, Pm, Sm, Eu, Gd, Tb, Dy, Ho, Er, Tm, Yb, and Lu,
L represents a single form composed of one element selected from Zr or Hf, or a mixed form thereof,
M represents at least one or more elements selected from a group consisting of Ce, Co, Fe, In, Mg, Mn, Ni, Sc, Yb, and Zn,
N represents at least one or more elements selected from a group consisting of Nb, Sb, Ta, and W, and
a, b, x, and y satisfy requisites: 0<a≤0.10, 0<b≤0.05, 0.05≤x≤0.58, and 0.05≤y≤0.62.

17. The epitaxy oxide thin film of claim 16, wherein in the formula, a piezoelectric single crystal satisfies the requisites of 0.01≤a≤0.10 and 0.01≤b≤0.05.

18. The epitaxy oxide thin film of claim 13, wherein the functional oxide electrode thin film is composed of a ferroelectric thin film based on HfO₂ having an orthorhombic structure.

19. The epitaxy oxide thin film of claim 18, wherein the ferroelectric thin film based on HfO₂ having the orthorhombic structure is a thin film of HfO₂ doped with any one selected from a group consisting of Zr, Si, Y, Gd, La, and Sr.
